(19) United States
(12) Patent Application Publication
(10) Pub. No.: US 2024/0138166 A1
(43) Pub. Date: Apr. 25, 2024

(54) IMAGE SENSORS AND ELECTRONIC DEVICES

(71) Applicant: Samsung Electronics Co., Ltd., Suwon-si (KR)

(72) Inventors: Younhee LIM, Suwon-si (KR); Kyung Bae PARK, Suwon-si (KR); Sungyoung YUN, Suwon-si (KR); Juhyung LIM, Suwon-si (KR)

(73) Assignee: Samsung Electronics Co., Ltd., Suwon-si (KR)

(21) Appl. No.: 18/475,796

(22) Filed: Sep. 27, 2023

(30) Foreign Application Priority Data
Sep. 30, 2022 (KR) 10-2022-0125799

(51) Int. Cl. H10K 39/32

(52) U.S. Cl. CPC H10K 39/32

(57) ABSTRACT

An image sensor includes a semiconductor substrate in which a plurality of photo-sensing elements are integrated, an organic active layer on the semiconductor substrate, an interlayer between the organic active layer and the semiconductor substrate, and optionally a color filter layer on the organic active layer. The organic active layer includes a singlet fission material. The interlayer includes a dielectric selected from an oxide, a nitride, oxynitride, fluoride, oxyfluoride, and any combination thereof.

### CROSS-REFERENCE TO RELATED APPLICATION

This application claims priority to and the benefit of Korean Patent Application No. 10-2022-0125799 filed in the Korean Intellectual Property Office on Sep. 30, 2022, the entire contents of which are incorporated herein by reference.

### BACKGROUND

### 1. Field

Image sensors and electronic devices are disclosed.

### 2. Description of the Related Art

CMOS image sensor using one or more silicon photodiodes have a pixel having a smaller size as the resolution of the CMOS image sensor becomes higher resolution. However, as the pixel size decreases, the light absorption area of the silicon photodiode decreases, and thus sensitivity of the CMOS image sensor may decrease. Therefore, the development of image sensors with high integration and high sensitivity characteristics is important.

Organic materials not only have a large extinction coefficient, but also have a characteristic of selectively absorbing only light in a specific wavelength region according to the molecular structure. When applied as a photoelectric conversion device of an image sensor, the photodiode and color filter may be replaced at the same time, which is desirable for an increase of sensitivity at high integration. Therefore, recently, studies have been attempted to apply to an image sensor using an organic photoelectric conversion material.

### SUMMARY

Some example embodiments provide an image sensor with a novel structure that is suitable for miniaturization, has high photoelectric conversion efficiency, and has excellent sensitivity.

Some example embodiments provide an electronic device including the image sensor.

According to some example embodiments, an image sensor may include a semiconductor substrate; a plurality of photo-sensing elements integrated in the semiconductor substrate; an organic active layer on the semiconductor substrate; an interlayer between the organic active layer and the semiconductor substrate; and optionally a color filter layer on the organic active layer. The organic active layer may include a singlet fission material. The interlayer may include a dielectric. The dielectric may be at least one of an oxide, a nitride, an oxynitride, a fluoride, an oxyfluoride, or any combination thereof.

At least one photo-sensing element of the plurality of photo-sensing elements may be a photodiode.

At least one photo-sensing element of the plurality of photo-sensing elements may include an inorganic semiconductor that is at least one of Si, Ge, GaAs, InP, GaN, AlN, CdTe, ZnTe, CuInₓGa₍₁₋ₓ₎S_{y}Se_{(2-y)}, wherein, 0≤x≤1 and 0≤y≤2, or any combination thereof.

The singlet fission material may include a single molecule, an oligomer, or a polymer.

The singlet fission material may include acene, polyene, rylene, rubrene, a quinoid-based compound, a biradicaloid, a derivative thereof, or any combination thereof.

The acene may be selected from anthracene, tetracene, pentacene, hexacene, heptacene, phenacene, or a derivative thereof.

The acene or the derivative thereof may be a compound represented by Chemical Formula 1.

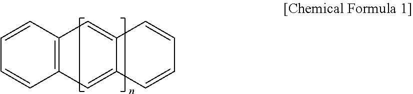

In Chemical Formula 1,
n may be an integer from 1 to 10, and
at least one hydrogen of at least one benzene ring may be independently present or may be replaced by deuterium, a halogen, a halogen-containing group, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof.

The polyene may include C4 to C20 diene, C4 to C20 triene, C4 to C20 traene, C4 to C20 dienol, C4 to C20 trienol, C4 to C20 traenol, C4 to C20 dienone, C4 to C20 trienone, C4 to C20 traenone, a derivative thereof, or any combination thereof. For example, polyene may include butadiene, butadienol, butadienone, hexatriene, hexatrienol, hexatrienone, octatetraene, octatetraenol, octatetraenone, dodecadiene, dodecadienol, undecadiene, undecadienol, tridecadiene, tridecadienol, tridecadienone, a derivative thereof, or any combination thereof.

The rylene may include perylene, terylene, quaterrylene, pentarylene, hexarylene, or any combination thereof.

The quinoid-based compound may include a compound represented by Chemical Formula 5-1 or Chemical Formula 5-2.

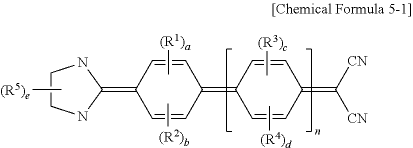

In Chemical Formula 5-1,
R¹, R², R³, R⁴, and R⁵ are each independently hydrogen, deuterium, a halogen, a halogen-containing group, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof, a, b, c, and d are each independently an integer of 0 to 4, a+b and c+d are each independently less than or equal to 4, e is an integer of 0 to 4, and n is an integer of 0 to 2.

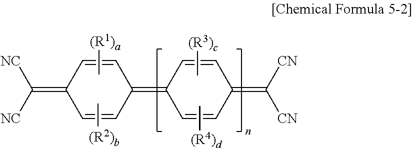

In Chemical Formula 5-2,
R¹, R², R³, and R⁴ are each independently hydrogen, deuterium, a halogen, a halogen-containing group, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof, a, b, c, and d are each independently an integer of 0 to 4, a+b and c+d are each independently less than or equal to 4, and n is an integer from 0 to 2.

The biradicaloid may include benzofuran, diphenyl isobenzofuran, a derivative thereof, or any combination thereof.

The singlet fission material may have an extinction coefficient of greater than or equal to about 1×10³ cm⁻¹ at one or more wavelengths in a visible light wavelength spectrum (about 300 nm to about 700 nm wavelength range).

The singlet fission material in a triplet excited state may have an energy bandgap of greater than or equal to about 1.0 eV and less than or equal to about 4.0 eV.

An energy bandgap of the singlet fission material may be equal to or greater than an energy bandgap of an inorganic semiconductor of at least one photo-sensing element of the plurality of photo-sensing elements.

The organic active layer may further include a metal porphyrin-based phosphorescent dopant.

An energy bandgap of the metal porphyrin-based phosphorescent dopant may be equal to or greater than an energy bandgap of an inorganic semiconductor of at least one photo-sensing element of the plurality of photo-sensing elements.

The dielectric may have a dielectric constant of about 2 to about 150.

The dielectric may include a Group 2A element, a Group 2B element, a Group 3A element, a Group 3B element, a Group 4A element, a Group 4B element, a Group 5A element, a Group 5B element, or any combination thereof.

The dielectric may include an oxide, nitride, oxynitride, fluoride, oxyfluoride, or any combination thereof including Si, Al, Sr, Ba, Mg, Ge, Ga, Ti, Zr, Hf, Ta, Nb, La, Y, Bi, Pb, or any combination thereof.

The oxide may include SiOₓ (0<x≤2), GeOₓ (0<x≤2), TiOₓ (0<x≤2), AlOₓ (0<x≤2), GaOₓ (0<x≤2), HfOₓ (0<x≤2), Al₂O₃, Ta₂O₅, La₂O₅, Y₂O₃, TiO₂, BaₓSr₁₋ₓTiO₃ (0<x<1, barium strontium titanate, BST), PbZrO₃, PbTiO₃, PbZrₓTi₁₋ₓO₃ (0<x<1), Pb₅Ge₃O₁₁, SrBi₂Ta₂O₉, BiLa₄Ti₃O₁₂, Bi₄Ti₃O₁₂, SrBi₂(TaNb)₂O₉, BaZr_{0.2}Ti_{0.8}O₃ (barium zirconium titanate, BZT), BaTiO₃, SrTiO₃, or any combination thereof.

The oxide may include a compound represented by Chemical Formula 7.

M₁M₂O₃ [Chemical Formula 7]

In Chemical Formula 7,
M₁ is at least one of Sr, Ba, Ca, or Pb, and M₂ is at least one of Ti, Zr, Mg, Nb, or Ta.

The nitrides may include SiNₓ (0<x≤2), GeNₓ (0<x≤2), TiNₓ (0<x≤2), AlNₓ (0<x≤2), GaNₓ (0<x≤2), HfNₓ (0<x≤2), or any combination thereof.

The oxynitride may include SiOₓN₄₋ₓ (0<x<4, e.g., 0.5≤x≤3), GeOₓN₄₋ₓ (0<x<4, e.g., 0.5≤x≤3), TiOₓN_{y} (0.5≤x≤3, 0<y≤2), AlOₓN_{y} (0.5≤x≤3, 0<y≤2), GaOₓN_{y} (0.5≤x≤3, 0<y≤2), HfOₓN_{y} (0.5≤x≤3, 0<y≤2), or any combination thereof.

The fluoride may include BaMgF₄, SrMgF₄, Ba₁₋ₓSrₓMgF₄ (0<x<1), BaZnF₄, Ba_{1-y}(Mg₁₋ₓZnₓ)_{1+y}F₄ (0≤x≤1, −0.2≤y≤0.2), or any combination thereof.

The oxyfluoride may include BaMgO_{z/2}F_{4-z} (0<z<4), SrMgO_{z/2}F_{4-z} (0<z<4), Ba₁₋ₓSrₓMgO_{z/2}F_{4-z} (0<x<1, 0<z<4), BaZnO_{z/2}F_{4-z} (0<z<4), Ba_{1-y}(Mg₁₋ₓZnₓ)_{1+y}O_{z/2}F_{4-z} (0≤x≤1, −0.2≤y≤0.2, 0<z<4), or any combination thereof.

The interlayer may have a thickness of less than or equal to about 20 nm.

The image sensor may further include a focusing lens on the organic active layer.

Some example embodiments provide an electronic device including the image sensor.

Since separate electrodes and circuits to collect charges of the organic active layer are not required, miniaturization is possible, and an image sensor with high photoelectric conversion efficiency and excellent sensitivity is provided.

### BRIEF DESCRIPTION OF THE DRAWINGS

FIG. 1 is a cross-sectional view showing an image sensor according to some example embodiments.

FIG. 2 is a schematic view illustrating a charge generation process of a singlet fission material in an organic active layer of an image sensor according to some example embodiments.

FIG. 3 is a schematic view of an electronic device according to some example embodiments.

FIG. 4 is a graph showing sensitivity according to pixel size of devices according to Example 1 and Comparative Example 1 according to some example embodiments.

### DETAILED DESCRIPTION

Hereinafter, some example embodiments of the present inventive concepts will be described in detail so that a person skilled in the art would understand the same. However, the inventive concepts may be embodied in many different forms and are not to be construed as limited to the example embodiments set forth herein.

In the drawings, the thickness of layers, films, panels, regions, etc., are exaggerated for clarity. Like reference numerals designate like elements throughout the specification.

It will be understood that when an element such as a layer, film, region, or substrate is referred to as being “on” another element, it may be directly on the other element or intervening elements may also be present. In contrast, when an element is referred to as being “directly on” another element, there are no intervening elements present.

In addition, unless explicitly described to the contrary, the word “comprise”, and variations such as “comprises” or “comprising”, will be understood to imply the inclusion of stated elements but not the exclusion of any other elements.

In addition, throughout the specification, when referring to “on a plane,” this means when the target portion is viewed from above, and when referring to “in cross-section,” this means when a cross section of the target portion is cut vertically and viewed from the side.

In the present specification, the singular form also includes the plural form unless specifically stated otherwise in the description.

As used herein, when specific definition is not otherwise provided, “substituted” refers to replacement of a hydrogen atom of a compound or group by a substituent selected from deuterium, a halogen atom (F, Br, Cl, or I), a nitro group, a cyano group, an amino group, an azido group, an amidino group, a hydrazino group, a hydrazono group, a carbonyl group, a carbamyl group, a thiol group, a C1 to C20 alkyl group, a C1 to C20 alkoxy group, a C2 to C20 alkenyl group, a C2 to C20 alkynyl group, a C6 to C30 aryl group, a C7 to C30 arylalkyl group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C2 to C20 heterocycloalkyl group, or any combination thereof.

As used herein, when a definition is not otherwise provided, “alkyl group” may be a linear or branched saturated monovalent hydrocarbon group (e.g., a methyl group, an ethyl group, a propyl group, an isobutyl group, a sec-butyl group, a tert-butyl group, a pentyl group, an iso-amyl group, a hexyl group, and the like).

As used herein, when a definition is not otherwise provided, “alkenyl group” refers to a linear or branched monovalent hydrocarbon group including at least one carbon-carbon double bond (e.g., an ethenyl group).

As used herein, when a definition is not otherwise provided, “alkynyl group” refers to a linear or branched monovalent hydrocarbon group including at least one carbon-carbon triple bond (e.g., an ethynyl group).

As used herein, when a definition is not otherwise provided, “alkoxy group” may refer to an alkyl group that is linked via an oxygen, e.g., a methoxy group, an ethoxy group, and a sec-butyloxy group.

As used herein, when a definition is not otherwise provided, “aryl group” refers to a monovalent functional group formed by the removal of one hydrogen atom from one ring of an arene, and may be a C6 to C30 aryl group, for example a C6 to C20 aryl group, e.g., a phenyl group or a naphthyl group. The arene refers to a hydrocarbon having an aromatic ring, and includes monocyclic and polycyclic hydrocarbons wherein the additional ring(s) of the polycyclic hydrocarbon may be aromatic or nonaromatic.

As used herein, when a definition is not otherwise provided, “heteroaryl group” refers to an aryl group including at least one heteroatom selected from N, O, S, Se, Te, P, and Si in the ring, and remaining carbons. When the heteroaryl group is a fused ring, the entire heteroaryl group or each ring may include one or more heteroatoms. Examples of the heteroaryl group may include a pyridyl group, a pyrazinyl group, a pyrimidinyl group, a pyrrolyl group, a thienyl group, a pyrazolyl group, an imidazolyl group, a thiazolyl group, an oxazolyl group, an isoxazolyl group, a thiadiazolyl group, an oxadiazolyl group, a furanyl group, a quinolinyl group, an isoquinolinyl group, and the like.

As used herein, when a definition is not otherwise provided, “heterocycloalkyl group” refers to a cycloalkyl group including at least one heteroatom selected from N, O, S, Se, Te, P, and Si and remaining carbons. When the heterocycloalkyl group is a fused ring, the entire heterocycloalkyl group or each ring may include one or more heteroatoms.

Hereinafter, unless otherwise defined, “halogen” means F, Cl, Br or I, and the halogen-containing group is a C1 to C30 haloalkyl group where at least one hydrogen of the C1 to C30 alkyl group is replaced with F, Cl, Br, or I or a C6 to C30 haloaryl group in which the hydrogen of the C6 to C30 aryl group is replaced by F, Cl, Br, or I. Examples of the haloalkyl group may include a fluoroalkyl group, for example, a perfluoroalkyl group.

As used herein, when a definition is not otherwise provided, “silyl group” may be represented by —SiRR′R″, wherein R, R′, and R″ are each independently hydrogen, a C1 to C30 alkyl group, a C2 to C30 alkenyl group, a C2 to C30 alkynyl group, a C6 to C30 aryl group, a C3 to C30 heteroaryl group, or any combination thereof.

As used herein, when a definition is not otherwise provided, “combination” in the definitions of a substituent refers to a mixture of two or more, substitution in which one substituent is substituted with another substituent, fusion with each other, or a linkage to each other by a single bond or a C1 to C10 alkylene group.

In addition, hereinafter, as used herein, when a definition is not otherwise provided, “combination” may refer to a mixture of two or more, an alloy of two or more, and a stacked structure of two or more.

In addition, hereinafter, as used herein, when a definition is not otherwise provided, “hetero” refers to including 1 to 3 heteroatoms selected from N, O, S, Se, Te, P, and Si.

Hereinafter, when specific definition is not otherwise provided, a work function or an energy level is expressed as an absolute value from a vacuum level. In addition, when the work function or energy level is referred to be deep, high, or large, it may have a large absolute value based on “0 eV” of the vacuum level while when the work function or energy level is referred to be shallow, low, or small, it may have a small absolute value based on “0 eV” of the vacuum level. Further, the differences between the work function and/or the energy level may be values obtained by subtracting a small value of the absolute value from a large value of the absolute value.

Hereinafter, when a definition is not otherwise provided, the energy level is the highest occupied molecular orbital (HOMO) energy level or the lowest unoccupied molecular orbital (LUMO) energy level.

The HOMO energy level may be evaluated with an amount of photoelectrons emitted by energy when irradiating UV light to a thin film using AC-2 (Hitachi) or AC-3 (Riken Keiki Co., Ltd.). The LUMO energy level may be obtained by obtaining a bandgap energy using a UV-Vis spectrometer (Shimadzu Corporation), and then calculating the LUMO energy level from the bandgap energy and the already measured HOMO energy level.

It will further be understood that when an element is referred to as being “on” another element, it may be above or beneath or adjacent (e.g., horizontally adjacent) to the other element. It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof. Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%, ±5%, ±3%, or ±1%). Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%, ±5%, ±3%, or ±1%). Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%, ±5%, ±3%, or ±1%). It will be understood that elements and/or properties thereof may be recited herein as being “identical” to, “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%, ±5%, ±3%, or ±1%) around the stated elements and/or properties thereof. While the term “same,” “equal” or “identical” may be used in description of some example embodiments, it should be understood that some imprecisions may exist. Thus, when one element is referred to as being the same as another element, it should be understood that an element or a value is the same as another element or value within a desired manufacturing or operational tolerance range (e.g., ±10%, ±5%, ±3%, or ±1%). When the terms “about” or “substantially” are used in this specification in connection with a numerical value, it is intended that the associated numerical value includes a manufacturing or operational tolerance (e.g., ±10%, ±5%, ±3%, or ±1%) around the stated numerical value. Moreover, when the words “about” and “substantially” are used in connection with geometric shapes, it is intended that precision of the geometric shape is not required but that latitude for the shape is within the scope of the inventive concepts. Further, regardless of whether numerical values or shapes are modified as “about” or “substantially,” it will be understood that these values and shapes should be construed as including a manufacturing or operational tolerance (e.g., ±10%, ±5%, ±3%, or ±1%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other. As described herein, the terms “contact” and “direct contact” may be used interchangeably.

As used herein, “Group” refers to a group of the periodic table of elements.

Below, an image sensor according to some example embodiments will be described with reference to the drawings. Herein, a CMOS image sensor is described as an example of an image sensor.

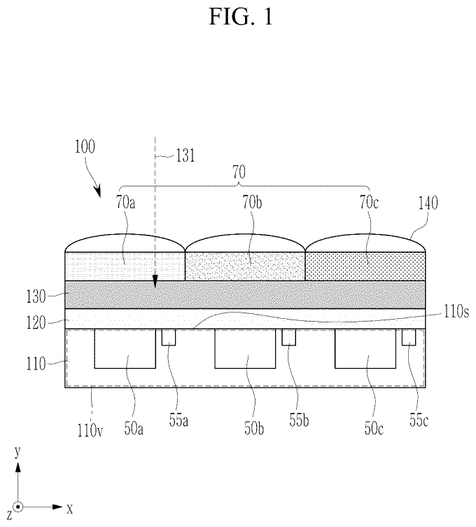

FIG. 1 is a cross-sectional view showing an image sensor according to some example embodiments.

Referring to FIG. 1, the image sensor 100 according to some example embodiments includes a semiconductor substrate 110, an organic active layer 130 on the semiconductor substrate 110, an interlayer 120 between the organic active layer 130 and the semiconductor substrate 110, and a color filter layer 70 on the organic active layer 130.

The semiconductor substrate 110 may be a silicon substrate, and photo-sensing elements 50a, 50b, and 50c, a transmission transistor (not shown), and charge storage 55a, 55b, and 55c may be integrated therein, for example such that each of the photo-sensing elements 50a, 50b, and 50c may be partially or entirely located within a volume space 110v defined by outermost surfaces (e.g., at least the upper surface 110s) of the semiconductor substrate 110, such that each of the photo-sensing elements 50a, 50b, and 50c may be partially or entirely within an interior of the semiconductor substrate 110. Accordingly, it will be understood that an element (e.g., each of the plurality of photo-sensing elements 50a, 50b, and 50c) that is described to be integrated in the semiconductor substrate 110 may be understood to be at least partially or entirely located within a volume space 110v defined by outermost surfaces (e.g., upper surface 110s) of the semiconductor substrate, such that the element (e.g., each of the plurality of photo-sensing elements 50a, 50b, and 50c) may be partially or entirely within an interior of the semiconductor substrate 110.

The photo-sensing elements 50a, 50b, and 50c may be photodiodes, such that each photo-sensing element of the photo-sensing elements 50a, 50b, and 50c may be understood to be a photodiode (e.g., a silicon photodiode).

The photo-sensing elements 50a, 50b, and 50c may include a p-n junction or a p-i-n junction.

The photo-sensing elements 50a, 50b, and 50c may each include an inorganic semiconductor selected from Si, Ge, GaAs, InP, GaN, AlN, CdTe, ZnTe, CuInₓGa₍₁₋ₓ₎S_{y}Se_{(2-y)}, wherein, 0≤x≤1, 0≤y≤2, and any combination thereof. For example, the inorganic semiconductor may be at least one of Si, Ge, GaAs, InP, GaN, AlN, CdTe, ZnTe, CuInₓGa₍₁₋ₓ₎S_{y}Se_{(2-y)}, wherein, 0≤x≤1, 0≤y≤2, or any combination thereof.

The photo-sensing elements 50a, 50b, and 50c, transmission transistors, and/or charge storages 55a, 55b, and 55c may be integrated for each pixel. For example, as shown in the drawing, the photo-sensing elements 50a, 50b, and 50c may each be included in red pixels, green pixels, and blue pixels, respectively. The photo-sensing elements 50a, 50b, and 50c may be configured to sense light, and the sensed information may be transmitted by a transmission transistor.

A CMOS circuit (not shown) may be disposed under the semiconductor substrate 110. The CMOS circuit may include a transmission transistor and/or a charge storage.

The organic active layer 130 is disposed on the semiconductor substrate 110, and the interlayer 120 is disposed between the organic active layer 130 and the semiconductor substrate 110.

The organic active layer 130 may include a singlet fission material, and the interlayer 120 includes a dielectric selected from an oxide, a nitride, an oxynitride, a fluoride, an oxyfluoride, and any combination thereof. For example, the interlayer 120 may include a dielectric that is at least one of an oxide, a nitride, an oxynitride, a fluoride, an oxyfluoride, or any combination thereof.

The singlet fission material refers to a substance that is configured to form a singlet exciton when a high-energy photon is absorbed (e.g., absorbed at the singlet fission material) by a multiple exciton generation mechanism, and the singlet exciton forms two triplet excitons by singlet fission.

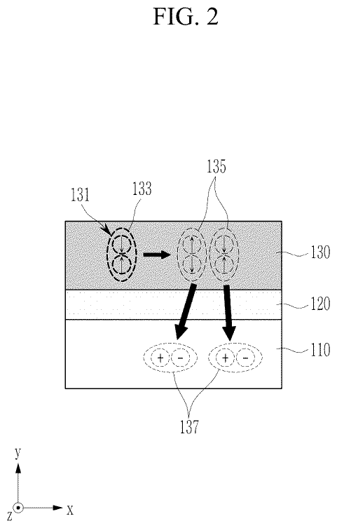

The mechanism (e.g., the multiple exciton generation mechanism) will be described with reference to FIG. 2.

FIG. 2 is a schematic view illustrating a charge generation process of a singlet fission material in an organic active layer of an image sensor according to some example embodiments.

Referring to FIGS. 1 and 2, the organic active layer 130 may be configured to absorb light 131 (e.g., incident light) from an exterior of the image sensor 100. For example light 131 may be received at and/or absorbed in the organic active layer 130 based on light 131 having passed through at least one focusing lens 140 and one or more color filters 70a, 70b, and/or 70c of the color filter layer 70. Referring to FIG. 2, when light 131 is absorbed in the organic active layer 130 (e.g., in response to light 131 being absorbed in the organic active layer 130), singlet excitons 133 are formed by a singlet fission material of the organic active layer 130, and the singlet excitons 133 are split into triplet excitons 135 in the organic active layer 130. The triplet excitons 135 pass through the interlayer 120 (e.g., from the organic active layer 130 and through the interlayer 120 as shown in FIG. 2) and are extracted into the semiconductor substrate 110 (e.g., from the interlayer 120 and into the semiconductor substrate 110 as shown in FIG. 2) as electron-hole pairs 137. Such electron-hole pairs 137 may thus be received at, and thus detected by, one or more of the photo-sensing elements 50a, 50b, and/or 50c that are integrated in the semiconductor substrate 110 (e.g., based on the electron-hole pairs 137 inducing photocurrent in one or more of the photo-sensing elements 50a, 50b, and/or 50c).

As described above, the singlet fission material may increase the number (e.g., quantity) of excitons through singlet fission (e.g., increase the quantity of excitons generated based on light 131 being absorbed in the organic active layer 130 through singlet fission), which may further increase the number of electron-hole pairs that are extracted into the semiconductor substrate 110 and detected by one or more of the photo-sensing elements 50a, 50b, and/or 50c, thereby improving the photoelectric conversion efficiency and sensitivity of the photo-sensing elements disposed below (e.g., increasing the photoelectric conversion efficiency and sensitivity of one or more of the photo-sensing elements 50a, 50b, and/or 50c that are integrated in the semiconductor substrate 110). As a result, the photoelectric conversion efficiency and sensitivity of the image sensor 100 may be improved, based on the organic active layer including a singlet fission material that may be configured to increase the quantity of excitons generated based on light 131 being absorbed in the organic active layer 130 through singlet fission and thus to increase the quantity of electron-hole pairs 137 received and/or detected at the photo-sensing elements 50a, 50b, and/or 50c for a given amount of light 131 received at the organic active layer 130. As a result, the image sensor 100 may generate images with improved signal to noise ratio, improved image quality, improved resolution, or the like and thus may have improved performance, and the image sensor 100 may have improved power consumption efficiency due to being configured to provide improved photoelectric conversion efficiency and sensitivity. For example, photoelectric conversion efficiency and sensitivity of the image sensor 100 may be improved without increased power consumption by the image sensor 100, based on the image sensor 100 being configured to increase the quantity of excitons generated based on light 131 being absorbed in the organic active layer 130 through singlet fission and thus to increase the quantity of electron-hole pairs 137 received and/or detected at the photo-sensing elements 50a, 50b, and/or 50c for a given amount of light 131 received at the organic active layer 130. In another example, photoelectric conversion efficiency and sensitivity of the image sensor 100 may be maintained with reduced power consumption by the image sensor 100, based on the image sensor 100 being configured to increase the quantity of excitons generated based on light 131 being absorbed in the organic active layer 130 through singlet fission and thus to increase the quantity of electron-hole pairs 137 received and/or detected at the photo-sensing elements 50a, 50b, and/or 50c for a given amount of light 131 received at the organic active layer 130.

The singlet fission material may include a single molecule, an oligomer, or a polymer.

The singlet fission material may include acene, polyene, rylene, rubrene, a quinoid-based compound, biradicaloid, a derivative thereof, or any combination thereof.

The acene may be selected from anthracene, tetracene, pentacene, hexacene, heptacene, phenacene, and any derivative thereof. The acene may be at least one of anthracene, tetracene, pentacene, hexacene, heptacene, phenacene, or any derivative thereof.

The acene or the derivative thereof may be a compound represented by Chemical Formula 1.

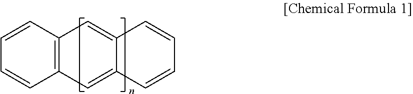

In Chemical Formula 1,
n may be an integer from 1 to 10,
the hydrogen of the benzene ring (e.g., at least one hydrogen of at least one benzene ring of Chemical Formula 1, at least one hydrogen of each benzene ring of Chemical Formula 1, etc.) may be replaced by deuterium, a halogen, a halogen-containing group, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof. For example, at least one hydrogen of at least one benzene ring of Chemical Formula 1 may be independently present (e.g., may not be replaced) or may be replaced by deuterium, a halogen, a halogen-containing group, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof.

The silyl group may be represented by —SiRR′R″, wherein R, R′, and R″ are each independently hydrogen, a C1 to C30 alkyl group, a C2 to C30 alkenyl group, a C2 to C30 alkynyl group, a C6 to C30 aryl group, a C3 to C30 heteroaryl group, or any combination thereof.

The derivative of the acene may be an aromatic compound in which at least one hydrogen of acene is replaced by a dithienyl group, a triisopropylsilyl (TIPS), a phenyl group, a butyl group, etc. Specific examples may include dithienyl tetracene, TIPS-tetracene, dibithienyl tetracene, diphenyl tetracene, TIPS-pentacene, diphenyl pentacene, dibiphenyl pentacene, dithienyl pentacene, or dibithienyl pentacene.

The derivative of the acene may include a structure in which two or more acenes such as anthracene, tetracene, pentacene, hexacene, heptacene, and phenacene are linked by a single bond, a C1 to C10 alkylene group, or a C6 to C10 arylene group. The derivative of the acene having this structure may include compounds represented by Chemical Formula 1-1.

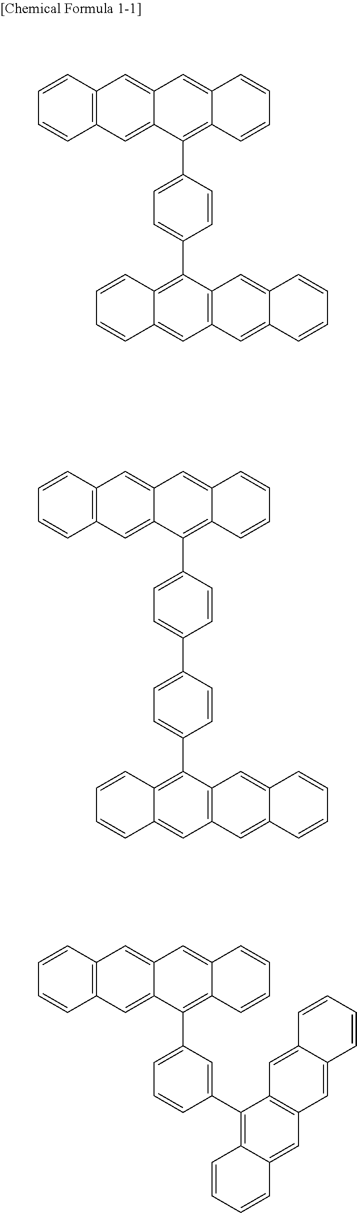

In Chemical Formula 1-1,
the hydrogen of the benzene ring (e.g., at least one hydrogen of at least one benzene ring) may be replaced by deuterium, a halogen, a halogen-containing group, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof. For example, at least one hydrogen of at least one benzene ring of Chemical Formula 1-1 may be independently present (e.g., may not be replaced) or may be replaced by deuterium, a halogen, a halogen-containing group, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof.

The silyl group may be represented by —SiRR′R″, wherein R, R′, and R″ are each independently hydrogen, a C1 to C30 alkyl group, a C2 to C30 alkenyl group, a C2 to C30 alkynyl group, a C6 to C30 aryl group, a C3 to C30 heteroaryl group, or any combination thereof.

The polyene may include C4 to C20 (e.g. C5 or more, C6 or more, C7 or more and C18 or less or C15 or less) diene, C4 to C20 (e.g. C5 or more, C6 or more, C7 or more and C18 or less or C15 or less) triene, C4 to C20 (e.g. C5 or more, C6 or more, C7 or more and C18 or less or C15 or less) traene, C4 to C20 (e.g. C5 or more, C6 or more, C7 or more and C18 or less or C15 or less) dienol, C4 to C20 (e.g. C5 or more, C6 or more, C7 or more and C18 or less or C15 or less) trienol, C4 to C20 (e.g. C5 or more, C6 or more, C7 or more and C18 or less or C15 or less) traenol, C4 to C20 (e.g. C5 or more, C6 or more, C7 or more and C18 or less or C15 or less) dienone, C4 to C20 (e.g. C5 or more, C6 or more, C7 or more and C18 or less or C15 or less) trienone, C4 to C20 (e.g. C5 or more, C6 or more, C7 or more and C18 or less or C15 or less) traenone, a derivative thereof, or any combination thereof. For example, polyene may include butadiene, butadienol, butadienone, hexatriene, hexatrienol, hexatrienone, octatetraene, octatetraenol, octatetraenone, dodecadiene, dodecadienol, undecadiene, undecadienol, tridecadiene, tridecadienol, tridecadienone, a derivative thereof, or any combination thereof. Herein, in the derivative thereof, the hydrogen present in the polyene chain (e.g., at least one hydrogen that is present in the polyene chain) may be replaced by deuterium, a halogen, a halogen-containing group, a cyano group, a hydroxy group, C1 to C30 alkyl group, C2 to C30 alkenyl group, C2 to C30 alkynyl group, C1 to C30 alkoxy group, C3 to C30 cycloalkyl group, C6 to C30 aryl group, C2 to C30 heterocycloalkyl group, C2 to C30 heteroaryl group, silyl group, or any combination thereof.

The derivative thereof may include diphenylbutadiene, diphenylhexatriene, or diphenyloctatetraene.

In the above polyenes, the combination thereof may mean a mixture of butadiene, hexatriene, octatetraene, etc., or polyenes in which two or more of butadiene, hexatriene, or octatetraene are linked together.

The polyene may include one of compounds represented by Chemical Formula 2 or any combination thereof.

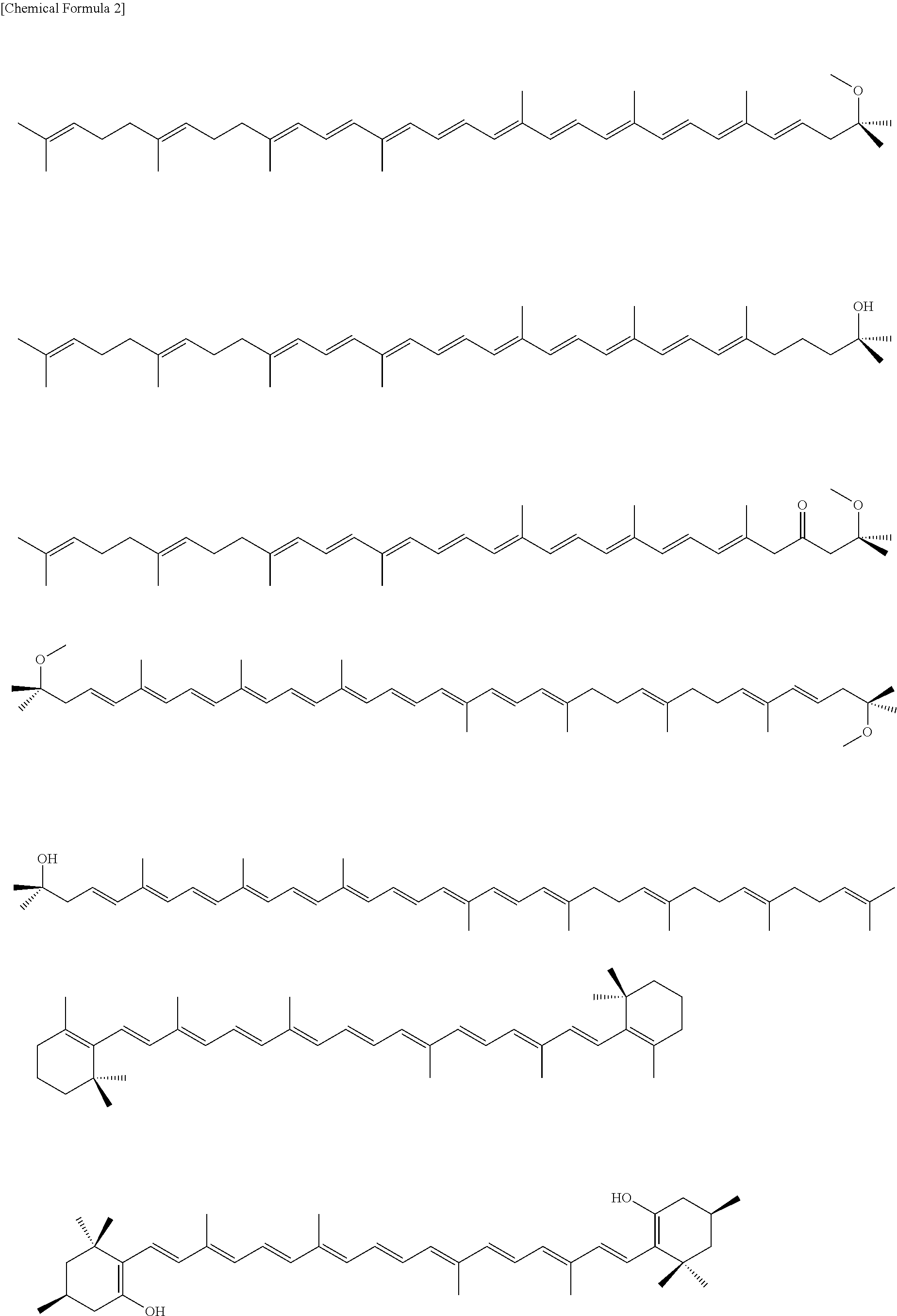

Specific examples of the rylene may include perylene, terylene, quaterrylene, pentarylene, hexarylene, or any combination thereof. The rylene may include the following structural unit represented by Chemical Formula 3:

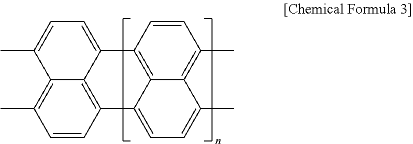

Wherein, in Chemical Formula 3, n may be 1, 2, 3, 4, 5, 6, 7 or 8.

In Chemical Formula 3, the hydrogen of the benzene ring (e.g., at least one hydrogen of at least one benzene ring) may be replaced by deuterium, a halogen, a halogen-containing group, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof. For example, at least one hydrogen of at least one benzene ring of Chemical Formula 3 may be independently present (e.g., may not be replaced) or may be replaced by deuterium, a halogen, a halogen-containing group, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof.

The rubrene or the derivative thereof may be represented by Chemical Formula 4.

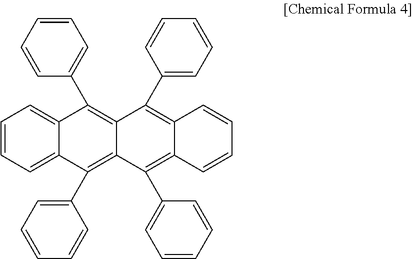 [SMILES: c1ccc(-c2c3ccccc3c(-c3ccccc3)c3c(-c4ccccc4)c4ccccc4c(-c4ccccc4)c23)cc1]

In Chemical Formula 4,
the hydrogen of the benzene ring (e.g., at least one hydrogen of at least one benzene ring of Chemical Formula 4) may be replaced by deuterium, a halogen, a halogen-containing group, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof. For example, at least one hydrogen of at least one benzene ring of Chemical Formula 4 may be independently present (e.g., may not be replaced) or may be replaced by deuterium, a halogen, a halogen-containing group, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof.

The silyl group may be represented by —SiRR′R″, wherein R, R′, and R″ are each independently hydrogen, a C1 to C30 alkyl group, a C2 to C30 alkenyl group, a C2 to C30 alkynyl group, a C6 to C30 aryl group, a C3 to C30 heteroaryl group, or any combination thereof.

The quinoid-based compound may include a compound represented by Chemical Formula 5-1 or Chemical Formula 5-2.

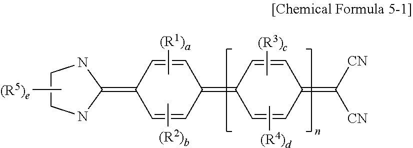

In Chemical Formula 5-1,
R¹, R², R³, R⁴, and R⁵ are each independently hydrogen, deuterium, a halogen, a halogen-containing group, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof, a, b, c, and d are each independently an integer of 0 to 4, a+b and c+d are each independently less than or equal to 4, e is an integer of 0 to 4, and n is an integer of 0 to 2.

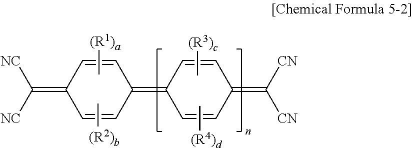

In Chemical Formula 5-2,
R¹, R², R³, and R⁴ are each independently hydrogen, deuterium, a halogen, a halogen-containing group, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof, a, b, c, and d are each independently an integer of 0 to 4, a+b and c+d are each independently less than or equal to 4, and n is an integer from 0 to 2.

The biradicaloid may include benzofuran, diphenyl isobenzofuran, a derivative thereof, or any combination thereof.

The biradicaloid may include a compound represented by Chemical Formula 6-1, Chemical Formula 6-2, or Chemical Formula 6-3.

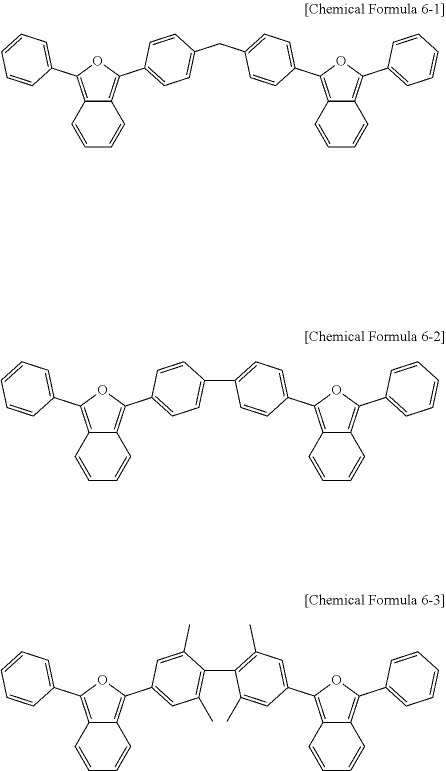 [SMILES: c1ccc(-c2oc(-c3ccc(Cc4ccc(-c5oc(-c6ccccc6)c6ccccc56)cc4)cc3)c3ccccc23)cc1 ; c1ccc(-c2oc(-c3ccc(-c4ccc(-c5oc(-c6ccccc6)c6ccccc56)cc4)cc3)c3ccccc23)cc1 ; Cc1cc(-c2oc(-c3ccccc3)c3ccccc23)cc(C)c1-c1c(C)cc(-c2oc(-c3ccccc3)c3ccccc23)cc1C]

In Chemical Formulas 6-1, 6-2, or 6-3,
the hydrogen of the benzene ring (e.g., at least one hydrogen of at least one benzene ring) may be replaced by deuterium, a halogen, a halogen-containing group, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof. For example, at least one hydrogen of at least one benzene ring of the compound represented by Chemical Formula 6-1, Chemical Formula 6-2, or Chemical Formula 6-3 may be independently present (e.g., may not be replaced) or may be replaced by deuterium, a halogen, a halogen-containing group, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof.

The singlet fission material may have an extinction coefficient of greater than or equal to about 1×10³ cm⁻¹, for example, greater than or equal to about 1.2×10³ cm⁻¹, or greater than or equal to about 1.5×10³ cm⁻¹ at one or more wavelengths in the visible light wavelength spectrum (about 300 nm to about 700 nm wavelength range). The singlet fission material may have an extinction coefficient of less than or equal to about 1×10⁴ cm⁻¹, for example less than or equal to about 9×10³ cm⁻¹ in the visible light wavelength spectrum. The extinction coefficient may be obtained by coating a singlet fission material on a glass substrate using a spin coating method to obtain a thin film, and measuring an absorbance at a maximum absorption wavelength of this thin film using a Shimadzu UV-3600 Plus UV-Vis-NIR spectrometer, and dividing the absorbance by the thickness of the thin film.

The singlet fission material in a triplet excited state may have an energy bandgap of greater than or equal to about 1.0 eV and less than or equal to about 4.0 eV, for example, greater than or equal to about 1.1 eV, greater than or equal to about 1.2 eV, greater than or equal to about 1.3 eV, greater than or equal to about 1.4 eV, greater than or equal to about 1.5 eV, greater than or equal to about 1.6 eV, greater than or equal to about 1.7 eV, greater than or equal to about 1.8 eV, greater than or equal to about 1.9 eV, greater than or equal to about 2.0 eV, greater than or equal to about 2.1 eV, greater than or equal to about 2.2 eV, or greater than or equal to about 2.3 eV and less than or equal to about 3.9 eV, less than or equal to about 3.8 eV, less than or equal to about 3.7 eV, less than or equal to about 3.6 eV, less than or equal to about 3.5 eV, less than or equal to about 3.4 eV, less than or equal to about 3.3 eV, less than or equal to about 3.2 eV, less than or equal to about 3.1 eV, less than or equal to about 3.0 eV, less than or equal to about 2.9 eV, less than or equal to about 2.8 eV, less than or equal to about 2.7 eV, or less than or equal to about 2.6 eV.

The energy bandgap (of the triplet energy) of the singlet fission material may be equal to or greater than the energy bandgap of the inorganic semiconductor of the photo-sensing elements 50a, 50b, and 50c. For example, a difference (E_{g1}−E_{g3}) between the energy bandgap (E_{g1}) of the singlet fission material and the energy bandgap (E_{g3}) of the inorganic semiconductor of the photo-sensing element may be greater than or equal to about 0.1 eV, for example, greater than or equal to about 0.15 eV, or greater than or equal to about 0.2 eV, for example less than or equal to about 5.0 eV. Within the above ranges, diffusion and transfer of excitons generated from the singlet fission material may be effectively achieved.

The organic active layer 130 may include two or more different singlet fission materials, or may be formed of a plurality of layers including different singlet fission materials. For example, the organic active layer 130 may include a first layer in contact with the interlayer 120 and a second layer on the first layer, and the energy bandgap (of triplet energy) of the singlet fission material (e.g., a second singlet fission material) included in the second layer may be equal to or greater than the energy band gap (of triplet energy) of the singlet fission material (e.g., a first singlet fission material) included in the first layer. For example, a difference in energy bandgap between the first layer and the second layer may be greater than or equal to about 0.1 eV, for example, greater than or equal to about 0.15 eV, or greater than or equal to about 0.2 eV.

The organic active layer 130 may further include a metal porphyrin-based phosphorescent dopant. The metal porphyrin-based phosphorescent dopant may be configured to emit light by receiving the energy of triplet excitons in the singlet fission material, and the inorganic semiconductor of the photo-sensing element may receive this light energy and be excited.

The metal porphyrin-based phosphorescent dopant may be included in an amount of about 0.1 to about 10 parts by weight based on 100 parts by weight of the singlet fission material in the organic active layer 130.

The metal of the metal porphyrin-based phosphorescent dopant may include Pt or Pd, and specific examples of the metal porphyrin-based phosphorescent dopant may include Pt(II) meso tetraphenyl tetrabenzoporphyrin, Pt(II) tetraphenyl benzoporphyrin, Pt(II) octaethyl porphyrin, Pd(II) tetrabenzoporphyrin, Pt(II) meso tetra(pentafluorophenyl)porphyrin, Pt(II) tetrabenzoporphyrin, Pd(II) meso-tetraphenylporphyrin, Pt(II) aza-tri phenyl tetrabenzoporphyrin, Pt(II) tetraphenyltetranaphtho[2,3]porphyrin, or any combination thereof.

The energy bandgap of the metal porphyrin-based phosphorescent dopant may be equal to or greater than the energy bandgap of the inorganic semiconductor of the photo-sensing elements 50a, 50b, and 50c. For example, a difference (E_{g2}−E_{g3}) between the energy bandgap (E_{g2}) of the metal porphyrin-based phosphorescent dopant and the energy bandgap (E_{g3}) of the inorganic semiconductor of the photo-sensing element may be greater than or equal to about 0.1 eV, for example, greater than or equal to about 0.15 eV, or greater than or equal to about 0.2 eV, for example less than or equal to about 5.0 eV. Within the above range, diffusion and transfer of excitons generated from the singlet fission material may be effectively achieved. The triplet excitons 135 generated from the singlet fission material may diffuse into the interlayer 120. The interlayer 120 may reduce, minimize, or prevent quenching of excitons and reduce, minimize, or prevent extracted electrons and holes from recombining on the surface of the semiconductor substrate 110. The interlayer 120 makes it easier to extract charges moving from the organic active layer 130 to the semiconductor substrate 110, thereby further reducing remaining charges and showing higher charge extraction efficiency, thereby improving photoelectric conversion efficiency and/or sensitivity of the image sensor 100, improving power consumption efficiency of the image sensor 100, or the like. Additionally, the interlayer 120 may serve as a passivation layer that protects the surface of the semiconductor substrate 110.

The interlayer 120 may include a dielectric having a dielectric constant (also called relative dielectric constant) of about 2 to about 150. The relative dielectric constant refers to a relative permittivity, which is a ratio of the dielectric constant of another material to the dielectric constant of vacuum. The dielectric constant of vacuum is 8.854×10⁻¹² F/m.

The dielectric may have a dielectric constant of greater than or equal to about 2.5, greater than or equal to about 3.0, greater than or equal to about 3.5, greater than or equal to about 4.0, greater than or equal to about 4.5, greater than or equal to about 5.0, greater than or equal to about 5.5, greater than or equal to about 6.0, greater than or equal to about 6.5, greater than or equal to about 7.0, greater than or equal to about 7.5, or greater than or equal to about 8.0 and less than or equal to about 145, less than or equal to about 140, less than or equal to about 135, less than or equal to about 130, less than or equal to about 125, less than or equal to about 120, less than or equal to about 115, less than or equal to about 110, less than or equal to about 105, less than or equal to about 100, less than or equal to about 95, less than or equal to about 90, less than or equal to about 85, less than or equal to about 80, less than or equal to about 75, less than or equal to about 70, less than or equal to about 65, less than or equal to about 60, less than or equal to about 55, less than or equal to about 50, less than or equal to about 45, less than or equal to about 40, less than or equal to about 35, or less than or equal to about 30.

The interlayer 120 may be formed of a plurality of layers. When the interlayer 120 is formed of a plurality of layers, the interlayer 120 may include dielectrics having different dielectric constants.

The dielectric may include an oxide including a Group 2A (Group 2), a Group 2B (Group 12) element, a Group 3A (Group 13) element, a Group 3B (Group 3, lanthanide) element, a Group 4A (Group 14) element, a Group 4B (Group 4) element, a Group 5A (Group 15) element, a Group 5B (Group 5) element, or any combination thereof; a nitride including a Group 2A (Group 2) element, a Group 2B (Group 12) element, a Group 3A (Group 13) element, a Group 3B (Group 3, lanthanide) element, a Group 4A (Group 14) element, a Group 4B (Group 4) element, a Group 5A (Group 15) element, a Group 5B (Group 5) element, or any combination thereof; an oxynitride including a Group 2A (Group 2), a Group 2B (Group 12) element, a Group 3A (Group 13) element, a Group 3B (Group 3, lanthanide) element, a Group 4A (Group 14) element, a Group 4B (Group 4) element, a Group 5A (Group 15) element, a Group 5B (Group 5) element, or any combination thereof; a fluoride including a Group 2A (Group 2), a Group 2B (Group 12) element, a Group 3A (Group 13) element, a Group 3B (Group 3, lanthanide) element, a Group 4A (Group 14) element, a Group 4B (Group 4) element, a Group 5A (Group 15) element, a Group 5B (Group 5) element, or any combination thereof; an oxyfluoride including a Group 2A (Group 2), a Group 2B (Group 12) element, a Group 3A (Group 13) element, a Group 3B (Group 3, lanthanide) element, a Group 4A (Group 14) element, a Group 4B (Group 4) element, a Group 5A (Group 15) element, a Group 5B (Group 5) element, or any combination thereof. The dielectric may include a Group 2A (Group 2) element, a Group 2B (Group 12) element, a Group 3A (Group 13) element, a Group 3B (Group 3, lanthanide) element, a Group 4A (Group 14) element, a Group 4B (Group 4) element, a Group 5A (Group 15) element, a Group 5B (Group 5) element, or any combination thereof.

The dielectric may include an oxide including Si, Al, Sr, Ba, Mg, Ge, Ga, Ti, Zr, Hf, Ta, Nb, La, Y, Bi, Pb, or any combination thereof; a nitride including Si, Al, Sr, Ba, Mg, Ge, Ga, Ti, Zr, Hf, Ta, Nb, La, Y, Bi, Pb, or any combination thereof; an oxynitride including Si, Al, Sr, Ba, Mg, Ge, Ga, Ti, Zr, Hf, Ta, Nb, La, Y, Bi, Pb, or any combination thereof; a fluoride including Si, Al, Sr, Ba, Mg, Ge, Ga, Ti, Zr, Hf, Ta, Nb, La, Y, Bi, Pb, or any combination thereof; an oxyfluoride including Si, Al, Sr, Ba, Mg, Ge, Ga, Ti, Zr, Hf, Ta, Nb, La, Y, Bi, Pb, or any combination thereof; or any combination thereof.

Specific examples of the oxide may include SiOₓ (0<x≤2), GeOₓ (0<x≤2), TiOₓ (0<x≤2), AlOₓ (0<x≤2), GaOₓ (0<x≤2), HfOₓ (0<x≤2), Al₂O₃, Ta₂O₅, La₂O₅, Y₂O₃, TiO₂, BaₓSr₁₋ₓTiO₃ (0<x<1, barium strontium titanate, BST), PbZrO₃, PbTiO₃, PbZrₓTi₁₋ₓO₃ (0<x<1), Pb₅Ge₃O₁₁, SrBi₂Ta₂O₉, BiLa₄Ti₃O₁₂, Bi₄Ti₃O₁₂, SrBi₂(TaNb)₂O₉, BaZr_{0.2}Ti_{0.8}O₃ (barium zirconium titanate, BZT), BaTiO₃, SrTiO₃, or any combination thereof.

As another example, the oxide may include a compound represented by Chemical Formula 7.

M₁M₂O₃ [Chemical Formula 7]

In Chemical Formula 7,
M₁ is one or more elements selected from Sr, Ba, Ca, and Pb, and M₂ is one or more elements selected from Ti, Zr, Mg, Nb, and Ta. For example, in Chemical Formula 7, M₁ may be at least one of Sr, Ba, Ca, or Pb, and M₂ may be at least one of Ti, Zr, Mg, Nb, or Ta.

Specific examples of the nitride may include SiNₓ (0<x≤2), GeNₓ (0<x≤2), TiNₓ (0<x≤2), AlNₓ (0<x≤2), GaNₓ (0<x≤2), HfNₓ (0<x≤2), or any combination thereof. Specific examples of the oxynitride may include SiOₓN₄₋ₓ (0<x<4, e.g., 0.5≤x≤3), GeOₓN₄₋ₓ (0<x<4, e.g., 0.5≤x≤3), TiOₓN_{y} (0.5≤x≤3, 0<y≤2), AlOₓN_{y} (0.5≤x≤3, 0<y≤2), GaOₓN_{y} (0.5≤x≤3, 0<y≤2), HfOₓN_{y} (0.5≤x≤3, 0<y≤2), or any combination thereof.

Specific examples of the fluoride may include BaMgF₄, SrMgF₄, Ba₁₋ₓSrₓMgF₄ (0<x<1), BaZnF₄, Ba_{1-y}(Mg₁₋ₓZnₓ)_{1+y}F₄ (0≤x≤1, −0.2≤y≤0.2), or any combination thereof.

Specific examples of the oxyfluoride may include BaMgO_{z/2}F_{4-z} (0<z<4), SrMgO_{z/2}F_{4-z} (0<z<4), Ba₁₋ₓSrₓMgO_{z/2}F_{4-z} (0<x<1, 0<z<4), BaZnO_{z/2}F_{4-z} (0<z<4), Ba_{1-y}(Mg₁₋ₓZnₓ)_{1+y}O_{z/2}F_{4-z} (0≤x≤1, −0.2≤y≤0.2, 0<z<4), or any combination thereof.

The interlayer 120 may have a thickness of less than or equal to about 20 nm, less than or equal to about 10 nm, less than or equal to about 5 nm, less than or equal to about 3 nm or less than or equal to about 1 nm. The interlayer 120 may have a thickness of greater than or equal to about 0.01 nm, for example, greater than or equal to about 0.02 nm, greater than or equal to about 0.03 nm, for example, greater than or equal to about 0.04 nm, or greater than or equal to about 0.05 nm. Within the above thickness ranges, diffusion and transfer of triplet excitons may be easily performed.

The organic active layer 130 and the interlayer 120 may be formed by a deposition method such as atomic layer deposition (ALD).

A triplet exciton transport layer may be further included between the organic active layer 130 and the interlayer 120. The triplet exciton transport layer may include a metal porphyrin-based phosphorescent dopant, and the metal porphyrin-based phosphorescent dopant is as described above.

The triplet exciton transport layer may be formed to have a thickness of less than or equal to about 50 nm, for example less than or equal to about 40 nm or less than or equal to about 30 nm, for example about 0.1 nm to about 50 nm.

As described above, excitons formed in the organic active layer 130 are transferred to the semiconductor substrate 110 through the interlayer 120, so a separate electrode or circuit for transferring charges formed in the organic active layer 130 is not required, so that the image sensor 100 may be miniaturized and simplified, thereby reducing complexity of the image sensor 100 and thus reducing manufacturing cost of the image sensor 100, reducing likelihood of manufacturing defects and improving reliability of the image sensor, etc.

Additionally, there is no need to install metal wires or pads to transfer charges to the top or bottom of the semiconductor substrate 110, making it possible to miniaturize and simplify the image sensor 100, thereby reducing complexity of the image sensor 100 and thus reducing manufacturing cost of the image sensor 100, reducing likelihood of manufacturing defects and improving reliability of the image sensor, etc.

A color filter layer 70 may be disposed on the organic active layer 130. The color filter layer 70 may include a plurality of color filters 70a, 70b, and 70c configured to selectively transmit light of a particular (or, alternatively, predetermined) wavelength spectrum within the visible light wavelength spectrum, and the plurality of color filters 70a, 70b, and 70c may be for example, arranged repeatedly along row and/or column directions. The plurality of color filters 70a, 70b, and 70c may selectively transmit light in the first, second, and third wavelength spectra belonging to the visible light wavelength spectrum.

The first, second and third wavelength spectra are different from each other and may be selected from, for example, a green wavelength spectrum, a red wavelength spectrum, a blue wavelength spectrum, or a combination thereof. The green wavelength spectrum may be, for example, about 500 nm to 600 nm; the red wavelength spectrum may be greater than about 600 nm and less than about 750 nm, and the blue wavelength spectrum may be greater than or equal to about 380 nm and less than about 500 nm.

Herein, the selectively transmitting of light of the first, second, and third wavelength spectra means that a peak wavelength of the transmission spectrum exists in the corresponding wavelength spectrum, the transmission spectrum within the corresponding wavelength spectrum is significantly higher than the transmission spectrum of the other wavelength spectrum, and a transmission spectrum within that wavelength spectrum is from about 70% to about 100%, about 75% to about 100%, about 80% to about 100%, about 85% to about 100%, about 90% to about 100%, or about 95% to about 100% of the total transmission spectrum.

The plurality of color filters 70a, 70b, and 70c may be selected from a green filter configured to selectively transmit light of a green wavelength spectrum, a red filter configured to selectively transmit light of a red wavelength spectrum, a blue filter configured to selectively transmit light of a blue wavelength spectrum, a cyan filter configured to selectively transmit light of a blue to green wavelength spectrum, a yellow filter configured to selectively transmit light of a green to red wavelength spectrum, and a magenta filter configured to selectively transmit light of a blue to red wavelength spectrum.

For example, the plurality of color filters 70a, 70b, and 70c may be a green filter, a red filter, and a blue filter, respectively. In another example, the plurality of color filters 70a, 70b, and 70c may be a cyan filter, a yellow filter, and a magenta filter, respectively.

A focusing lens 140 may be further formed on the color filter layer 70. The focusing lens 140 may be formed on the organic active layer 130. The focusing lens 140 may collect the light to a single point by controlling the direction of the incident light at a light incident position. The focusing lens 140 may have a shape of, for example, a cylinder or a hemisphere, but is not limited thereto. In some example embodiments, the color filter layer 70 may be omitted, and the focusing lens 140 may be formed on (e.g., directly or indirectly on) the organic active layer 130.

The image sensor can be applied to (e.g., included in) electronic devices such as various display devices. Electronic devices such as display devices may be applied to, for example, mobile phones, video phones, smart phones, smart pads, smart watches, digital cameras, tablet PCs, laptop PCs, notebook computers, computer monitors, wearable computers, televisions, digital broadcasting terminals, e-books, personal digital assistants (PDAs), portable multimedia player (PMP), enterprise digital assistant (EDA), head mounted display (HMD), vehicle navigation, Internet of Things (IoT), Internet of all things (IoE), drones, door locks, safes, automatic teller machines (ATM), security devices, medical devices, or automotive electronic components, but are not limited thereto.

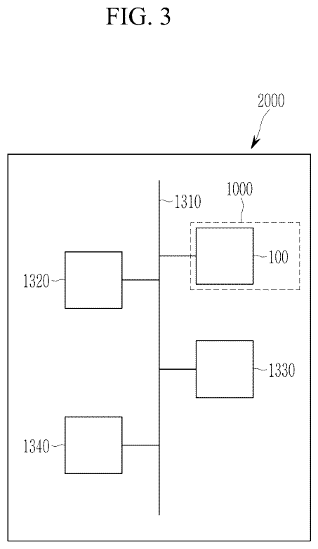

FIG. 3 is a schematic view illustrating an electronic device according to some example embodiments.

Referring to FIG. 3, electronic device 2000 may include the image sensor 100 according to any of the example embodiments. In some example embodiments, including the example embodiments shown in FIG. 3, the image sensor 100 may be included in a sensor-embedded display panel 1000 (e.g., a light emitting diode (LED) display panel, an organic LED (OLED) display panel, or the like), such that the electronic device 2000 may include a sensor-embedded display panel 1000 that may include the image sensor 100, but example embodiments are not limited thereto, and in some example embodiments the image sensor 100 may not be included in any display panel. Still referring to FIG. 3, in addition to the aforementioned constituent elements (e.g., an image sensor 100), the electronic device 2000 may further include a bus 1310, a processor 1320, a memory 1330, and at least one additional device 1340. Information of the aforementioned image sensor 100 and/or of the aforementioned sensor-embedded display panel 1000, processor 1320, memory 1330, and at least one additional device 1340 may be transmitted to each other through the bus 1310.

The processor 1320 may include one or more articles of processing circuitry such as a hardware including logic circuits; a hardware/software combination such as processor-implemented software; or any combination thereof. For example, the processing circuitry may be a central processing unit (CPU), an arithmetic logic unit (ALU), a digital signal processor, a microcomputer, a field programmable gate array (FPGA), System-on-Chip (SoC), a programmable logic unit, a microprocessor, an application-specific integrated circuit (ASIC), and the like. As an example, the processing circuitry may include a non-transitory computer readable storage device. The processor 1320 may control, for example, a display operation of the sensor-em bedded display panel 1000 or a sensor operation of the image sensor 100.

The memory 1330 may store an instruction program, and the processor 1320 may perform a function related to the sensor-embedded display panel 1000 by executing the stored instruction program.

The at least one additional device 1340 may be one or more communication interfaces (e.g., wireless communication interfaces, wired interfaces), user interfaces (e.g., keyboard, mouse, buttons, etc.), power supply and/or power supply interfaces, or any combination thereof. In some example embodiments, the at least one additional device 1340 may include a display panel (e.g., an LED display panel, an OLED display panel, etc.) that is separate from the image sensor 100 (e.g., a display panel that is not a sensor-embedded display panel).

The units and/or modules described herein may be implemented using hardware constituent elements and software constituent elements. For example, the hardware constituent elements may include microphones, amplifiers, band pass filters, audio-to-digital converters, and processing devices. The processing device may be implemented using one or more hardware devices configured to perform and/or execute program code by performing arithmetic, logic, and input/output operations. The processing device may include a processor, a controller and an arithmetic logic unit, a digital signal processor, a microcomputer, a field programmable array, a programmable logic unit, a microprocessor, or any other device capable of responding to and executing instructions. The processing device may access, store, operate, process, and generate data in response to execution of an operating system (OS) and one or more software running on the operating system.

The software may include a computer program, a code, an instruction, or any combination thereof, and may transform a processing device for a special purpose by instructing and/or configuring the processing device independently or collectively to operate as desired. The software and data may be implemented permanently or temporarily as signal waves capable of providing or interpreting instructions or data to machines, parts, physical or virtual equipment, computer storage media or devices, or processing devices. The software may also be distributed over networked computer systems so that the software may be stored and executed in a distributed manner. The software and data may be stored by one or more non-transitory computer readable storage devices.

The method according to any of the foregoing example embodiments may be recorded in a non-transitory computer readable storage device including program instructions for implementing various operations of the aforementioned embodiments. The storage device may also include program instructions, data files, data structures, and the like alone or in combination. The program instructions recorded in the storage device may be specially designed for some example embodiments or may be known to those skilled in computer software and available for use. Examples of non-transitory computer-readable storage devices may include magnetic media such as hard disks, floppy disks, and magnetic tapes; optical media such as CD-ROM discs, DVDs and/or blue-ray discs; magneto-optical media such as optical disks; and a hardware device configured to store and execute program instructions such as ROM, RAM, flash memory, and the like. The aforementioned device may be configured to operate as one or more software modules to perform the operations of any of the aforementioned embodiments.

Hereinafter, some example embodiments are illustrated in more detail with reference to examples. However, the present scope of the inventive concepts is not limited to the following examples.

### EXAMPLE 1

SiO₂ is deposited at 150° C. using an atomic layer deposition (ALD) to a thickness of 1 nm on a silicon substrate integrated with Si photodiodes to form an interlayer, rubrene is deposited at a rate of 0.35 Å/min at 280° C. under a vacuum of 10⁻⁷ torr to a thickness of 30 nm to form an organic active layer, and a red color filter (95.8% at a wavelength of 610 nm) is formed to produce a red light device (Example R). In the same way, SiO₂ is deposited at 150° C. using an atomic layer deposition (ALD) to a thickness of 1 nm on a silicon substrate integrated with Si photodiodes to form an interlayer, rubrene is deposited at a rate of 0.35 Å/min at 280° C. under a vacuum of 10⁻⁷ torr to a thickness of 30 nm to form an organic active layer, and a green color filter (91.5% at a wavelength of 540 nm) was formed to produce a green light device (Example G), and SiO₂ is deposited at 150° C. using an atomic layer deposition (ALD) to a thickness of 1 nm on a silicon substrate integrated with Si photodiodes to form an interlayer, rubrene is deposited at a rate of 0.35 Å/min at 280° C. under a vacuum of 10⁻⁷ torr to a thickness of 30 nm to form an organic active layer, and a blue color filter (80% at a wavelength of 450 nm) is formed to produce a blue light device (Example B).

### EXAMPLE 2

SiO_{1/2}N is deposited to a thickness of 1 nm on a silicon substrate integrated with Si photodiodes to form an interlayer, rubrene is deposited to a thickness of 30 nm to form an organic active layer, and a red filter is formed to produce a red light device (Example R). In the same way, SiO_{1/2}N is deposited to a thickness of 1 nm on a silicon substrate integrated with Si photodiodes to form an interlayer, rubrene is deposited to a thickness of 30 nm to form an organic active layer, and a green filter was formed to produce a green light device (Example G), and SiO_{1/2}N is deposited to a thickness of 1 nm on a silicon substrate integrated with Si photodiodes to form an interlayer, rubrene is deposited to a thickness of 30 nm to form an organic active layer, and a blue filter was formed to produce a blue light device (Example B).

### COMPARATIVE EXAMPLE 1

A red light device (Comparative Example R), a green light device (Comparative Example G), and a blue light device (Comparative Example B) are produced in the same manner as Example 1, except that the interlayer and the organic active layer are not formed.

### Evaluation 1: External Quantum Efficiency

For the devices according to Example 1 and Comparative Example 1, the external quantum efficiency (EQE) of the device according to Comparative Example 1 is measured and the external quantum efficiency of the device according to Example 1 is calculated using Equation 1 and the results are shown in Table 1. The EQE of the device according to Comparative Example 1 is measured by the IPCE (Incident Photon to Current Efficiency) method in a wavelength region of 380 nm to 800 nm while applying a reverse bias of 0 V to 10 V. The EQE of the device according to Example 1 is calculated assuming that rubrene in the organic active layer absorbs photons and 100% generates two excitons through singlet fission.

EQE=EQE_{Si}*T_{org}+2×(1−T_{org}) [Equation 1]

In Equation 1,
EQE is the external quantum efficiency of the device according to Example 1, EQE_{Si} is the external quantum efficiency of the device according to Comparative Example 1, and T_{org} is the transmittance of the organic active layer.

T_{org} is obtained by depositing an organic active layer of 30 nm on Quartz and measuring it with a UV-Visible spectrophotometer.

TABLE 1

| | Absorption | |
|---|---|---|
| | wavelength (nm) | EQE max (%) |
| Example 1 | R (600 nm) | 63.40 |
| | G (520 nm) | 112.73 |
| | B (450 nm) | 87.32 |
| Comparative | R (600 nm) | 62.64 |
| Example 1 | G (520 nm) | 75.99 |
| | B (450 nm) | 69.65 |

Referring to Table 1, the external quantum efficiency of the device according to Example 1 is improved compared to the device according to Comparative Example 1. Specifically, the red light device according to Example 1 is 1.21% more improved compared to the red light device of Comparative Example 1; the green light device according to Example 1 is 48.3% more improved compared to the green light device of Comparative Example 1; and the blue light device according to Example 1 is 25.3% more improved compared to the blue light device according to Comparative Example 1.

### Evaluation 2: Sensitivity

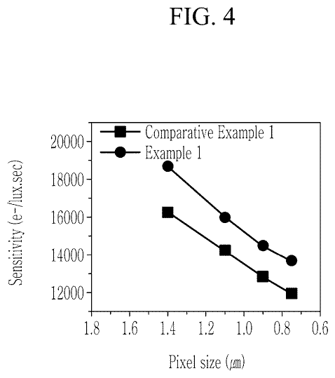

The number (e.g., quantity) of photons (Nₚₕ) irradiated to each pixel (pixel sizes: 1.4 μm×1.4 μm, 1.1 μm×1.1 μm, 0.9 μm×0.9 μm, and 0.75 μm×0.75 μm) per second is integrated for 1 Lux illumination of the CIE standard light source D65 light source. The sensitivity is calculated by multiplying Nₚₕ and EQE (EQE obtained in Evaluation 1) and integrating from 400 nm to 700 nm. Sensitivity according to pixel size is calculated and shown in FIG. 4. Referring to FIG. 4, when the pixel size is 1.4 μm×1.4 μm, the device of Example 1 is improved by about 2400 e⁻/lux·sec compared to the device of Comparative Example 1.

While the inventive concepts have been described in connection with what is presently considered to be practical example embodiments, it is to be understood that the inventive concepts are not limited to such example embodiments. On the contrary, the scope of the inventive concepts is intended to cover various modifications and equivalent arrangements included within the spirit and scope of the appended claims.

### DESCRIPTION OF SYMBOLS

| | |
|---|---|
| 100: image sensor | 110: semiconductor substrate |
| 120: interlayer | 130: organic active layer |
| 50a, 50b, 50c: photo-sensing element | |
| 55a, 55b, 55c: charge storage | |
| 70a, 70b, 70c: color filter | |
| 70: color filter layer | |

What is claimed is:

1. An image sensor, comprising:
a semiconductor substrate;
a plurality of photo-sensing elements integrated in the semiconductor substrate;
an organic active layer on the semiconductor substrate;
an interlayer between the organic active layer and the semiconductor substrate; and
optionally a color filter layer on the organic active layer,
wherein the organic active layer includes a singlet fission material and the interlayer includes a dielectric, the dielectric is an oxide, a nitride, an oxynitride, a fluoride, an oxyfluoride, or any combination thereof.

2. The image sensor of claim 1, wherein
at least one photo-sensing element of the plurality of photo-sensing elements is a photodiode.

3. The image sensor of claim 1, wherein
at least one photo-sensing element of the plurality of photo-sensing elements includes an inorganic semiconductor, the inorganic semiconductor is Si, Ge, GaAs, InP, GaN, AlN, CdTe, ZnTe, CuInₓGa₍₁₋ₓ₎S_{y}Se_{(2-y)}, wherein, 0≤x≤1, 0≤y≤2, or any combination thereof.

4. The image sensor of claim 1, wherein
the singlet fission material includes a single molecule, an oligomer, or a polymer.

5. The image sensor of claim 1, wherein
the singlet fission material includes acene, polyene, rylene, rubrene, a quinoid-based compound, a biradicaloid, a derivative thereof, or any combination thereof.

6. The image sensor of claim 5, wherein
the acene or the derivative thereof is a compound represented by Chemical Formula 1: 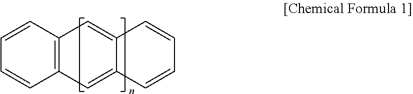
wherein, in Chemical Formula 1,
n is an integer from 1 to 10, and
at least one hydrogen of at least one benzene ring is independently present or is replaced by deuterium, a halogen, a halogen-containing group, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof.

7. The image sensor of claim 5, wherein
the polyene includes C4 to C20 diene, C4 to C20 triene, C4 to C20 traene, C4 to C20 dienol, C4 to C20 trienol, C4 to C20 traenol, C4 to C20 dienone, C4 to C20 trienone, C4 to C20 traenone, a derivative thereof, or any combination thereof.

8. The image sensor of claim 5, wherein
the rylene includes perylene, terylene, quaterrylene, pentarylene, hexarylene, or any combination thereof.

9. The image sensor of claim 5, wherein
the quinoid-based compound includes a compound represented by Chemical Formula 5-1 or Chemical Formula 5-2: 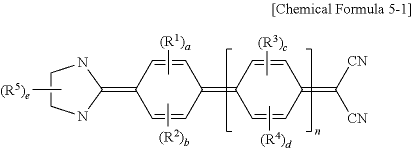
wherein, in Chemical Formula 5-1,
R¹, R², R³, R⁴, and R⁵ are each independently hydrogen, deuterium, a halogen, a halogen-containing group, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof,
a, b, c, and d are each independently an integer of 0 to 4,
a+b and c+d are each independently less than or equal to 4,
e is an integer of 0 to 4, and
n is an integer of 0 to 2, 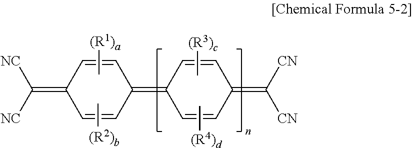
wherein, in Chemical Formula 5-2,
R¹, R², R³, and R⁴ are each independently hydrogen, deuterium, a halogen, a halogen-containing group, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof,
a, b, c, and d are each independently an integer of 0 to 4,
a+b and c+d are each independently less than or equal to 4, and
n is an integer from 0 to 2.

10. The image sensor of claim 5, wherein
the biradicaloid includes benzofuran, diphenyl isobenzofuran, a derivative thereof, or any combination thereof.

11. The image sensor of claim 1, wherein
The singlet fission material has an extinction coefficient of greater than or equal to about 1×10³ cm⁻¹ at one or more wavelengths in a visible light wavelength spectrum.

12. The image sensor of claim 1, wherein
the singlet fission material in a triplet excited state has an energy bandgap of greater than or equal to about 1.0 eV and less than or equal to about 4.0 eV.

13. The image sensor of claim 1, wherein
an energy bandgap of the singlet fission material is equal to or greater than an energy bandgap of an inorganic semiconductor of at least one photo-sensing element of the plurality of photo-sensing elements.

14. The image sensor of claim 1, wherein
the organic active layer further includes a metal porphyrin-based phosphorescent dopant.

15. The image sensor of claim 14, wherein
an energy bandgap of the metal porphyrin-based phosphorescent dopant is equal to or greater than an energy bandgap of an inorganic semiconductor of at least one photo-sensing element of the plurality of photo-sensing elements.

16. The image sensor of claim 1, wherein
the dielectric has a dielectric constant of about 2 to about 150.

17. The image sensor of claim 1, wherein
the dielectric includes a Group 2A element, a Group 2B element, a Group 3A element, a Group 3B element, a Group 4A element, a Group 4B element, a Group 5A element, a Group 5B element, or any combination thereof.

18. The image sensor of claim 1, wherein
the interlayer has a thickness of less than or equal to 20 nm.

19. The image sensor of claim 1, further comprising:
a focusing lens on the organic active layer.

20. An electronic device comprising the image sensor of claim 1.
